(19) United States
(12) Patent Application Publication
(10) Pub. No.: US 2016/0085150 A1
(43) Pub. Date: Mar. 24, 2016

(54) PHOTORESIST COMPOSITION AND METHOD OF MANUFACTURING CIRCUIT PATTERN USING THE SAME

(71) Applicant: Samsung Display Co. Ltd., Yongin-City (KR)

(72) Inventors: Jeong Won KIM, Seoul (KR); Kwang Woo PARK, Hwaseong-si (KR); Seung Bo SHIM, Asan-si (KR); Jun Hyuk WOO, Yongin-si (KR); Jin Ho JU, Seoul (KR)

(21) Appl. No.: 14/627,690

(22) Filed: Feb. 20, 2015

(30) Foreign Application Priority Data
Sep. 19, 2014 (KR) 10-2014-0125130

(51) Int. Cl. G03F 7/038; H05K 3/06

(52) U.S. Cl. CPC G03F 7/0384; H05K 3/06

(57) ABSTRACT

A photoresist composition includes an alkali soluble resin, a photosensitive compound, a first solvent having a boiling point of less than 200° C., and a second solvent having a boiling point of equal to or greater than 200° C.

This application claims priority to Korean Patent Application No. 10-2014-0125130 filed on Sep. 19, 2014, and all the benefits accruing therefrom under 35 U.S.C. §119, the content of which in its entirety is herein incorporated by reference.

### BACKGROUND OF THE INVENTION

1. Field

The present invention relates to a photoresist composition and a method of manufacturing a circuit pattern by using the same.

2. Description of the Related Art

To form a fine circuit pattern such as a display circuit or a semiconductor integrated circuit, a photoresist composition is typically evenly coated or spread on an insulating layer or a conductive metal layer formed on a substrate.

After the coating of the photoresist composition, a chemical vapor deposition (“VCD”) process may be performed in combination with a pre-bake process in order to remove a solvent contained in the photoresist composition. In the VCD process, the substrate coated with the photoresist composition may be placed inside a chamber, and a high vacuum created inside the chamber by operating a vacuum pump. Then, the solvent contained in the photoresist composition is generally dried by increasing the temperature inside the chamber.

After the drying of the solvent, the photoresist composition may be exposed to light in the presence of a mask having a predetermined shape and then developed to produce a pattern of an intended shape. Then, the metal layer or the insulating layer may be etched using the mask, and the remaining layer of photoresist composition removed. As a result, a fine circuit may be formed on the substrate.

### SUMMARY

Embodiments of the invention provide a photoresist composition having improved properties such as profile, critical dimension (“CD”) and residual film thickness (“dTPR”).

According to exemplary embodiments of the invention, a photoresist composition includes an alkali soluble resin, a photosensitive compound, a first solvent having a boiling point of less than 200° C., and a second solvent having a boiling point of equal to or greater than 200° C.

In an exemplary embodiment, the alkali soluble resin may include at least one of novolac resin, acrylic resin, siloxane resin, or polyimide resin.

In an exemplary embodiment, the photosensitive compound may be a diazide-based photosensitive compound.

In an exemplary embodiment, the first solvent may be at least one of ethyl cellosolve acetate, methyl cellosolve acetate, propylene glycol monoethyl ether acetate, propylene glycol monomethyl ether acetate, ethyl acetate, butyl acetate, propyl acetate, ethyl lactate, propylene glycol monomethyl ether, propylene glycol monoethyl ether; 2-methoxyethyl acetate, methyl 3-methoxypropionate, ethyl 3-ethoxypropionate and a combination thereof.

In an exemplary embodiment, the second solvent may be at least one of diethylene glycol monoisopropyl ether, ethylene glycol monohexyl ether, dipropylene glycol dimethyl ether, triethylene glycol dimethyl ether and dimethyl glutarate and a combination thereof.

In an exemplary embodiment, the amount of the alkali soluble resin may be about 10% to about 25% by weight, the amount of the photosensitive compound may be about 1% to about 10% by weight, the amount of the first solvent may be about 65% to about 85% by weight, and the amount of the second solvent may be about 1% to about 8% by weight, based on the total weight of the photoresist composition.

In an exemplary embodiment, the amount of the second solvent may be about 5% to about 7% by weight.

In an exemplary embodiment, the alkali soluble resin may be novolac resin having a meta-cresol to para-cresol ratio of 30:70 to 70:30 by weight.

In an exemplary embodiment, the photosensitive compound is a diazide-based photosensitive compound selected from at least one of 2,3,4-trihydroxybenzophenone-1,2-naphthoquinonediazide-5-sulfonate, 2,3,4,4-tetrahydroxybenzophenone-1,2-naphthoquinonediazide-5-sulfonate, naphthoquinone-1,2-diazide-5-sulfonyl chloride, naphthoquinone-1,2-diazide-4-sulfonyl chloride and mixture thereof.

In an exemplary embodiment, the diazide-based photosensitive compound may be a combination of 2,3,4-trihydroxybenzophenone-1,2-naphthoquinonediazide-5-sulfonate and 2,3,4,4-tetrahydroxybenzophenone-1,2-naphthoquinonediazide-5-sulfonate.

In an exemplary embodiment, the ratio of 2,3,4-trihydroxybenzophenone-1,2-naphthoquinonediazide-5-sulfonate to 2,3,4,4-tetrahydroxybenzophenone-1,2-naphthoquinonediazide-5-sulfonate may be 20:80 to 80:20 by weight.

In an exemplary embodiment, the first solvent may have a vapor pressure of greater than 0.1 torr, and the second solvent may have a vapor pressure of equal to or greater than 0.1 torr.

According to other embodiments of the invention, a method of manufacturing a circuit pattern includes: forming a conductive layer on a substrate, forming an etch pattern on the conductive layer using a photoresist composition which includes an alkali soluble resin, a photosensitive compound, and a mixture of a first solvent having a boiling point of less than 200° C. and a second solvent having a boiling point of equal to or greater than 200° C., and etching the conductive layer using the etch pattern as an etch mask.

According to exemplary embodiments, a coating layer formed from a photoresist composition can be made to have uniform properties such as profile, CD and dTPR, by reducing the volatility of the solvent contained in the photoresist composition.

Therefore, it is possible to improve the etching accuracy and uniformity of a fine circuit pattern formed using a coating layer including the exemplary photoresist composition disclosed herein as a mask.

### BRIEF DESCRIPTION OF THE DRAWINGS

The above and other aspects, advantages and features of the invention will become more apparent by describing in further detail exemplary embodiments thereof with reference to the accompanying drawings, in which:

FIG. 1 is a graph illustrating the change in critical dimension (CD) versus VCD pressure (torr) for Comparative Example 1 (FIG. 1A), Inventive example 1 (FIG. 1B), Inventive example 2 (FIG. 1C) and Inventive example 3 (FIG. 1D);

FIG. 2 is a graph illustrating the change in the profile (PR) of a photoresist composition versus VCD pressure for Comparative Example 1 (FIG. 2A), Inventive example 1 (FIG. 2B), Inventive example 2 (FIG. 2C) and Inventive example 3 (FIG. 2D);

FIG. 3 is a scanning electron microscope (SEM) photograph showing the change in the profile of the photoresist composition of Comparative example 1 under high VCD pressure (FIG. 3A) and under low VCD pressure (FIG. 3B);

FIG. 4 is a graph illustrating the change in the residual film thickness (dTPR) of a photoresist composition with respect to VCD pressure for Comparative Example 1 (FIG. 4A), Inventive example 1 (FIG. 4B), Inventive example 2 (FIG. 4C) and Inventive example 3 (FIG. 4D); and

FIGS. 5 through 13 are cross-sectional views illustrating steps of an exemplary embodiment of a method of manufacturing a circuit pattern on a thin-film transistor display panel.

### DETAILED DESCRIPTION OF THE INVENTION

The invention now will be described more fully hereinafter with reference to the accompanying drawings, in which various embodiments are shown. The inventive concept may, however, be embodied in many different forms and should not be construed as being limited to the embodiments set forth herein. Rather, these embodiments are provided so that this disclosure will be thorough and complete and will fully convey the concept of the inventive concept to those skilled in the art. Like reference numerals refer to like elements throughout.

In the drawings, the thickness of layers and regions are exaggerated for clarity. It will be understood that when an element or layer is referred to as being “on,” “connected to” or “coupled to” another element or layer, the element or layer can be directly on, connected or coupled to another element or layer, or intervening elements or layers may be present therebetween. In contrast, when an element is referred to as being “directly on,” “directly connected to” or “directly coupled to” another element or layer, there are no intervening elements or layers present. As used herein, connected may refer to elements being physically, electrically and/or fluidly connected to each other.

It will be understood that when an element is referred to as being “on” another element, it can be directly on the other element or intervening elements may be present therebetween. In contrast, when an element is referred to as being “directly on” another element, there are no intervening elements present.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, the singular forms “a,” “an,” and “the” are intended to include the plural forms, including “at least one,” unless the content clearly indicates otherwise. “Or” means “and/or.” As used herein, the term “and/or” includes any and all combinations of one or more of the associated listed items. It will be further understood that the terms “comprises,” “comprising,” “includes” and/or “including,” when used in this specification, specify the presence of stated features, integers, operations, elements, and/or components, but do not preclude the presence or addition of one or more other features, integers, steps, operations, elements, components, and/or groups thereof.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10%, 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

Exemplary embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

An exemplary embodiment of a photoresist composition according to the invention will now be described with reference to inventive and comparative examples.

In an exemplary embodiment, the photoresist composition of the invention may include an alkali soluble resin, a photosensitive compound, and a mixture of a first solvent having a boiling point of less than 200° C. and a second solvent having a boiling point of equal to or greater than 200° C.

The alkali soluble resin can be any resin that dissolves easily in an alkaline solution. In the following inventive and comparative examples, novolac resin was used. However, the alkali soluble resin can be any known alkali soluble resin such as acrylic resin, siloxane resin, or polyimide resin.

The novolac resin can be obtained by the addition-condensation reaction of a phenolic compound with an aldehyde compound.

Examples of the phenolic compound may include phenol, o-cresol, m-cresol, p-cresol, 2,5-xylenol, 3,5-xylenol, 3,4-xylenol, 2,3,5-trimethylphenol, 4-t-butylphenol, 2-t-butylphenol, 3-t-butylphenol, 3-ethylphenol, 2-ethylphenol, 4-ethylphenol, 3-methyl-6-t-butylphenol, 4-methyl-2-t-butylphenol, 2-naftol, 1,3-dihydroxynaphthalene, 1,7-dihydroxynaphthalene, and 1,5-dihydroxynaphthalene, which can be used alone or in a combination thereof.

Examples of the aldehyde compound may include formaldehyde, paraformaldehyde, acetaldehyde, propyl aldehyde, benzaldehyde, phenylaldehyde, α- and β-phenylpropyl aldehyde, o-, m-, and p-hydroxybenzaldehyde, glutaraldehyde, glyoxal, and o- and p-methylbenzaldehyde, which can be used alone or in a combination thereof.

The addition-condensation reaction of the phenol compound with the aldehyde compound for preparing the novolac resin may be performed using a conventional method, for example, in the presence of an acid catalyst. The addition-condensation reaction may be performed at a reaction temperature of about 60° C. to about 250° C. for a time period of about 2 to about 30 hours.

The acid catalyst may include organic acids, inorganic acids, divalent metal salts, or a combination thereof. Examples of the organic acids may include oxalic acid, formic acid, trichloroacetic acid, and p-toluenesulfonic acid. Examples of the inorganic acids may include hydrochloric acid, sulfuric acid, perchloric acid, and phosphoric acid. Examples of divalent metal salts may include zinc acetate and magnesium acetate. The addition-condensation reaction may be performed in a solvent or bulk.

When the alkali soluble resin has a weight-average molecular weight of about 2,000 to about 50,000 Da, as measured using a polystyrene standard, maximum photosensitivity of the photoresist composition can be obtained without reducing the development margin, residual film thickness, and thermal resistance of the photoresist composition. In addition, the damage to a photo-pattern formed from the photoresist composition can be minimized. Therefore, in exemplary embodiments, the weight-average molecular weight of the alkali soluble resin is about 2,000 to about 50,000.

The alkali soluble resin may be used in an amount of about 10% to about 25% by weight. When the content of the alkali soluble resin is about 10% to about 25% by weight, the development margin, residual film thickness, thermal resistance, and photosensitivity of the photoresist composition can be maximized.

In an exemplary embodiment, novolac resin having meta-cresol and para-cresol monomers in a ratio of 30:70 to 70:30 by weight is used in an amount of about 10% to about 25% by weight of the photoresist composition.

When not exposed to light, a diazide-based photosensitive compound may react with the alkali soluble resin and insolubilize the alkali soluble resin by crosslinking the alkali soluble resin. On the other hand, when exposed to light, the diazide-based photosensitive compound may decompose and dissolve in the alkaline solution without reacting with the alkali soluble resin.

The diazide-based photosensitive compound is not limited to a particular type and can be any diazide-based photosensitive compound known in the art to which the invention pertains.

Examples of the diazide-based photosensitive compound may include 2,3,4-trihydroxybenzophenone-1,2-naphthoquinonediazide-5-sulfonate, 2,3,4,4-tetrahydroxybenzophenone-1,2-naphthoquinonediazide-5-sulfonate, naphthoquinone-1,2-diazide-5-sulfonyl chloride, and naphthoquinone-1,2-diazide-4-sulfonyl chloride, which can be used alone or in mixture.

In exemplary embodiments, a diazide-based photosensitive compound which is a mixture of 2,3,4-trihydroxybenzophenone-1,2-naphthoquinonediazide-5-sulfonate and 2,3,4,4-tetrahydroxybenzophenone-1,2-naphthoquinonediazide-5-sulfonate in a ratio of 20:80 to 80:20 by weight, is used in an amount of about 1% to about 10% by weight.

When the diazide-based photosensitive compound is used in an amount of about 1% to about 10% by weight, residual film thickness can be improved, and photosensitivity can be maximized.

The mixture of the first solvent and the second solvent can be made into a solution by dissolving the alkali soluble resin and the diazide-based photosensitive compound. The mixture of the first solvent and the second solvent can be used to adjust the viscosity of the photoresist composition.

The first solvent is an organic solvent having a boiling point of less than 200° C. Examples of the first solvent may include glycol ether esters such as ethyl cellosolve acetate, methyl cellosolve acetate, propylene glycol monoethyl ether acetate, and propylene glycol monomethyl ether acetate; glycol ethers such as ethyl acetate, butyl acetate, propyl acetate, ethyl lactate, propylene glycol monomethyl ether, and propylene glycol monoethyl ether; 2-methoxyethyl acetate; methyl 3-methoxypropionate; and ethyl 3-ethoxypropionate.

The amount of the first solvent may be about 65% to 85% by weight of the photoresist composition.

In an exemplary embodiment, the first solvent may be an organic solvent having a vapor pressure of more than 0.1 torr. The first solvent having a vapor pressure of more than 0.1 torr may be propylene glycol monomethyl ether acetate or a mixture of propylene glycol monomethyl ether acetate and ethyl 3-ethoxypropionate.

The second solvent is an organic solvent having a boiling point of 200° C. or higher. Examples of the second solvent may include diethylene glycol monoisopropyl ether, ethylene glycol monohexyl ether, triethylene glycol dimethyl ether, triethylene glycol dimethyl ether, and dimethyl glutarate.

The amount of the second solvent may be in a range of about 1% to about 8% by weight of the photoresist composition. In an exemplary embodiment, the content of the second solvent may be about 5% to about 7% by weight. When the second solvent is present in an amount of about 5% to about 7% by weight, the photoresist composition may be improved in terms of profile, residual film thickness, and critical dimension (CD) value.

The second solvent may be an organic solvent having a vapor pressure of 0.1 torr or more. Examples of the second solvent having a vapor pressure of 0.1 torr or more may be diethylene glycol monoisopropyl ether, ethylene glycol monohexyl ether, dipropylene glycol dimethyl ether, triethylene glycol dimethyl ether, or dimethyl glutarate.

The photoresist composition may further include an additive, a surfactant, a plasticizer, a sensitizer, etc. as long as the function of each of the components of the photoresist composition (e.g. alkali soluble resin, the photosensitive compound, e.g. quinonediazide-based compound, and the phenolic compound) are not undermined.

### Inventive Example 1

A photoresist composition was prepared by mixing 15 g of novolac resin having meta-cresol and para-cresol monomers mixed in a ratio of 6:4 by weight, 3 g of a diazide-based photosensitive compound which is a combination of 2,3,4-trihydroxybenzophenone-1,2-naphthoquinonediazide-5-sulfonate and 2,3,4,4-tetrahydroxybenzophenone-1,2-naphthoquinonediazide-5-sulfonate mixed in a ratio of 5:5 by weight, 86 g of propylene glycol monoethyl ether acetate (“PGMEA”), 10 g of ethyl 3-ethoxypropionate (“EEP”), and 4 g of dimethyl glutarate (“DMMGA”).

### Inventive Example 2

A photoresist composition was prepared by mixing 15 g of novolac resin having meta-cresol and para-cresol monomers mixed in a ratio of 6:4 by weight, 3 g of a diazide-based photosensitive compound which is a combination of 2,3,4-trihydroxybenzophenone-1,2-naphthoquinonediazide-5-sulfonate and 2,3,4,4-tetrahydroxybenzophenone-1,2-naphthoquinonediazide-5-sulfonate mixed in a ratio of 5:5 by weight, 84 g of propylene glycol monoethyl ether acetate (PGMEA), 10 g of ethyl 3-ethoxypropionate, and 6 g of dimethyl glutarate (DMMGA).

### Inventive Example 3

A photoresist composition was prepared by mixing 15 g of novolac resin having meta-cresol and para-cresol monomers mixed in a ratio of 6:4 by weight, 3 g of a diazide-based photosensitive compound which is a combination of 2,3,4-trihydroxybenzophenone-1,2-naphthoquinonediazide-5-sulfonate and 2,3,4,4-tetrahydroxybenzophenone-1,2-naphthoquinonediazide-5-sulfonate mixed in a ratio of 5:5 by weight, 82 g of propylene glycol monoethyl ether acetate (PGMEA), 10 g of ethyl 3-ethoxypropionate (EEP), and 8 g of dimethyl glutarate (DMMGA).

### Comparative Example 1

A photoresist composition was prepared by mixing 15 g of novolac resin having meta-cresol and para-cresol monomers mixed in a ratio of 6:4 by weight, 3 g of a diazide-based photosensitive compound which is a combination of 2,3,4-trihydroxybenzophenone-1,2-naphthoquinonediazide-5-sulfonate and 2,3,4,4-tetrahydroxybenzophenone-1,2-naphthoquinonediazide-5-sulfonate mixed in a ratio of 5:5 by weight, 90 g of propylene glycol monoethyl ether acetate, and 10 g of ethyl 3-ethoxypropionate.

The composition and ratios by weight of the photoresist compositions of Inventive examples 1 through 3 and Comparative example 1 are summarized in Table 1 below. Table 2 shows the amounts of novolac resin, the photosensitive compound, the first solvent, and the second solvent included in each of the photoresist compositions of Inventive examples 1 through 3 and Comparative example 1, in terms of percent (%) by weight.

TABLE 1

| Make-up of photoresist | | Inventive | Inventive | Inventive | Comparative |
|---|---|---|---|---|---|
| composition | | example 1 | example 2 | example 3 | example 1 |
| Novolac resin (g) | | 15 | 15 | 15 | 15 |
| Photosensitive | | 3 | 3 | 3 | 3 |
| compound (g) | | | | | |
| First | PGMEA (g) | 86 | 84 | 82 | 90 |
| solvent | EEP (g) | 10 | 10 | 10 | 10 |
| Second | DMMGA (g) | 4 | 6 | 8 | 0 |
| solvent | | | | | |

| | | | | |
|---|---|---|---|---|
| Total (g) | 118 | 118 | 118 | 118 |

TABLE 2

| Make-up of photoresist | | Inventive | Inventive | Inventive | Comparative |
|---|---|---|---|---|---|
| composition | | example 1 | example 2 | example 3 | example 1 |
| Novolac resin | | 12.7 | 12.7 | 12.7 | 12.7 |
| (% by weight) | | | | | |
| Photosensitive | | 2.5 | 2.5 | 2.5 | 2.5 |
| compound | | | | | |
| (% by weight) | | | | | |
| First | PGMEA (% | 72.9 | 71.2 | 69.5 | 76.3 |
| solvent | by weight) | | | | |
| | EEP (% by | 8.5 | 8.5 | 8.5 | 8.5 |
| | weight) | | | | |
| Second | DMMGA (% | 3.4 | 5.1 | 6.8 | 0.0 |
| solvent | by weight) | | | | |

| | | | | |
|---|---|---|---|---|
| Total (% by weight) | 100 | 100 | 100 | 100 |

### Experimental Example 1

A substrate coated with the photoresist compositions of Inventive examples 1 through 3 and Comparative example 1 in a line shape was placed in a vacuum drying (VCD) chamber, and the CD of each of the photoresist compositions according to pressure was measured.

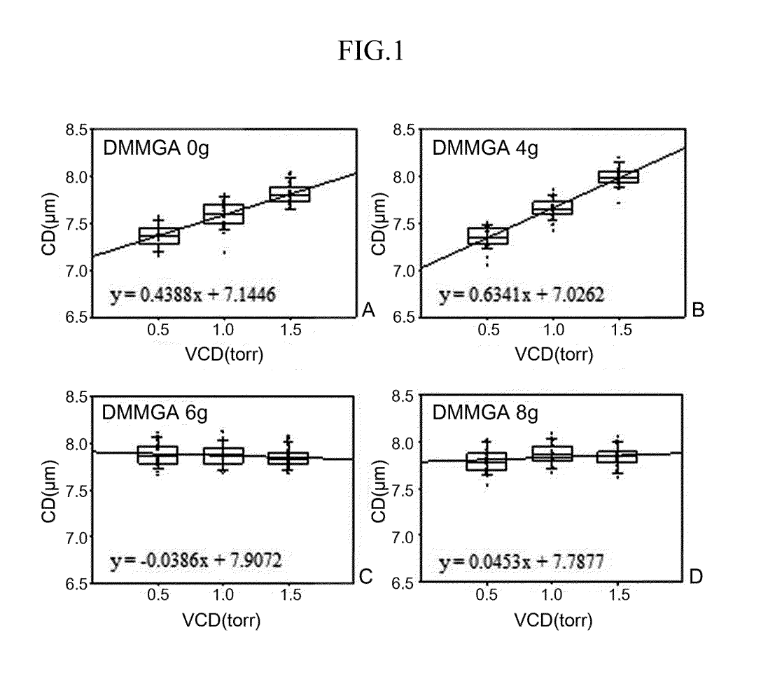

FIG. 1 is a graph illustrating the change in CD with respect to VCD pressure. Specifically, FIG. 1A illustrates the change in the CD versus the change in VCD pressure for the photoresist composition of Comparative example 1, which contains 0 g of DMMGA. FIG. 1B illustrates the change in the CD versus the change in VCD pressure for the photoresist composition of Inventive example 1, which contains 4 g of DMMGA. FIG. 1C illustrates the change in the CD versus the change in VCD pressure for the photoresist composition of Inventive example 2, which contains 6 g of DMMGA. FIG. 1D illustrates the change in the CD versus the change in VCD pressure for the photoresist composition of Inventive example 3, which contains 8 g of DMMGA.

Referring to FIGS. 1A through 1D, as the content of DMMGA increases, the change in CD value with respect to VCD pressure is reduced. That is, as the content of DMMGA increases, the CD value with respect to VCD pressure becomes more uniform.

As apparent from the result of the experiment, when the amount of DMMGA is 6 g (6.8 weight %) or more, the photoresist composition has drying uniformity without being affected by the VCD pressure.

### Experimental Example 2

A substrate coated with the photoresist compositions of Inventive examples 1 through 3 and Comparative example 1 in a line shape was placed in a VCD chamber, and the profile of each of the photoresist compositions was measured at different pressures using a scanning electronic microscope (SEM).

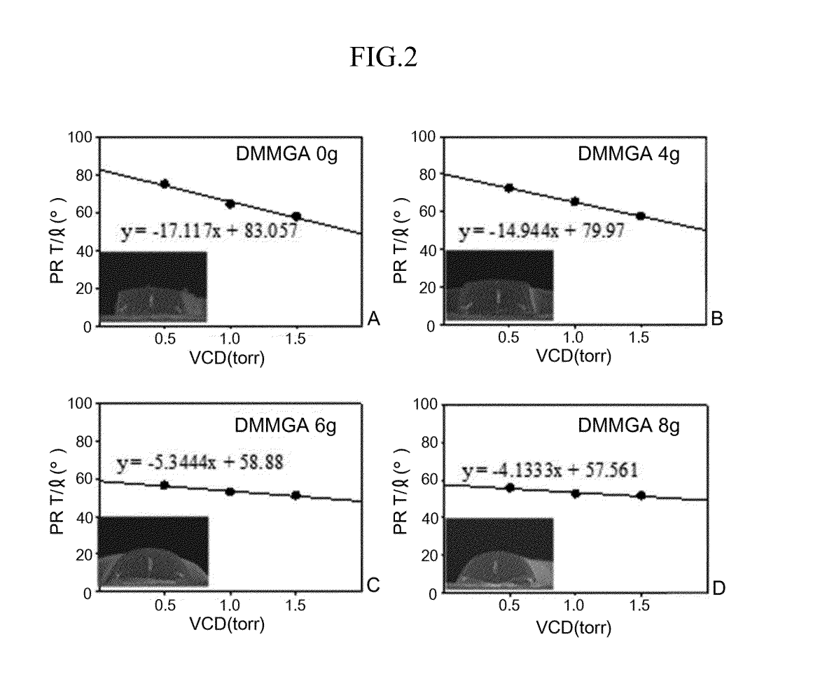

FIG. 2 is a graph illustrating the change in the profile of a photoresist composition versus VCD pressure. Specifically, FIG. 2A illustrates the change in the profile of the photoresist composition versus the change in VCD pressure for Comparative example 1, which contains 0 g of DMMGA. FIG. 2B illustrates the change in the profile of the photoresist composition versus the change in VCD pressure for Inventive example 1, which contains 4 g of DMMGA. FIG. 2C illustrates the change in the profile of the photoresist composition versus the change in VCD pressure for Inventive example 2, which contains 6 g of DMMGA. FIG. 2D illustrates the change in the profile of the photoresist composition versus the change in VCD pressure for Inventive example 3, which contains 8 g of DMMGA.

Referring to FIGS. 2A through 2D, as the content of DMMGA increases, the change in profile with respect to VCD pressure is reduced. That is, as the content of DMMGA increases, the profile with respect to VCD pressure becomes uniform. As apparent from the result of the experiment, when DMMGA is 6 g (6.8 weight %) or more, the profile of a photoresist composition is uniform without being affected by VCD pressure.

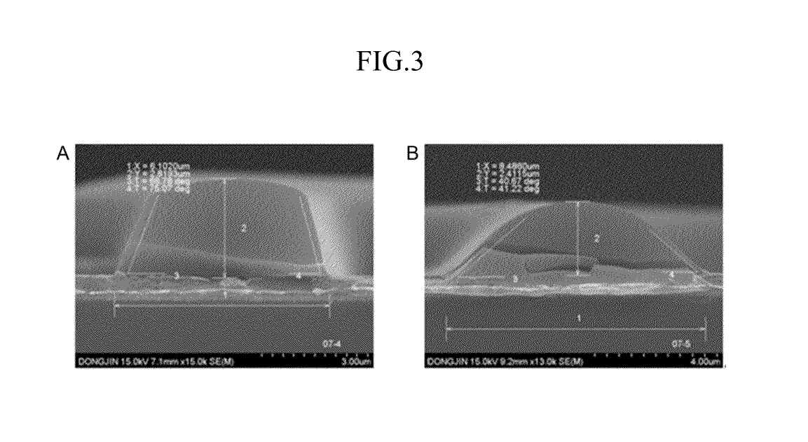

FIG. 3 is an SEM photograph showing the change in the profile of the photoresist composition of Comparative example 1 with respect to VCD pressure.

Specifically, FIG. 3A is an SEM photograph of the photoresist composition vacuum-dried under high VCD pressure, and FIG. 3B is an SEM photograph of the photoresist composition vacuum-dried under low VCD pressure.

Referring to FIGS. 3A and 3B, the profile of the photoresist composition of FIG. 3A has a greater taper angle and a greater residual film thickness (dTPR) than the profile of the photoresist composition of FIG. 3A by approximately 30 degrees and 0.4 μm, respectively.

Comparative example 1 containing 0 g of DMMGA dried differently according to VCD pressure, resulting in a great difference in the profile of the photoresist composition. On the other hand, Inventive examples 3 and 4 containing 6 g (6.8 weight %) or more of DMMGA did not dry much differently according to VCD pressure. Therefore, the profiles of the photoresist compositions were uniform.

### Experimental Example 3

A substrate coated with the photoresist compositions of Inventive examples 1 through 3 and Comparative example 1 in a line shape was placed in a VCD chamber, and the residual film thickness of each of the photoresist compositions according to pressure was measured.

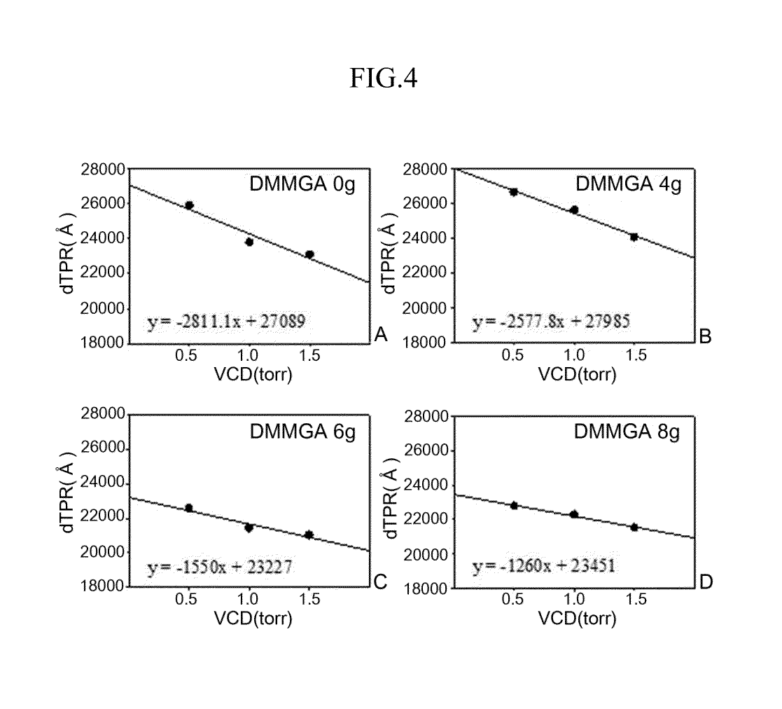

FIG. 4 is a graph illustrating the change in the residual film thickness of a photoresist composition with respect to VCD pressure. Specifically, FIG. 4A illustrates the change in the residual film thickness (measured in Angstroms (Å)) versus the change in VCD pressure for the photoresist composition of Comparative example 1, which contains 0 g of DMMGA. FIG. 4B illustrates the change in the residual film thickness versus the change in VCD pressure for the photoresist composition of Inventive example 1, which contains 4 g of DMMGA. FIG. 4C illustrates the change in the residual film thickness versus the change in VCD pressure for the photoresist composition of Inventive example 2, which contains 6 g of DMMGA, with respect to VCD pressure. FIG. 4D illustrates the change in the residual film thickness versus the change in VCD pressure for the photoresist composition of Inventive example 3, which contains 8 g of DMMGA.

Referring to FIGS. 4A through 4D, as the content of DMMGA increases, the change in residual film thickness with respect to VCD pressure is reduced. That is, as the content of DMMGA increases, residual film thickness with respect to the VCD pressure becomes more uniform.

As apparent from the result of the experiment, when DMMGA is used in amounts of 6 g (6.8 weight %) or more, the change in the residual film thickness of a photoresist composition is reduced

In exemplary embodiments, a method of manufacturing a circuit pattern of the invention may include forming a conductive layer on a substrate using a conductive material; forming an etch pattern on the conductive layer using a photoresist composition which includes an alkali soluble resin, a photosensitive compound, and a mixture of a first solvent having a boiling point of less than 200° C. and a second solvent having a boiling point of equal to or greater than 200° C.; and forming a conductive layer pattern by etching the conductive layer using the etch pattern as an etch mask.

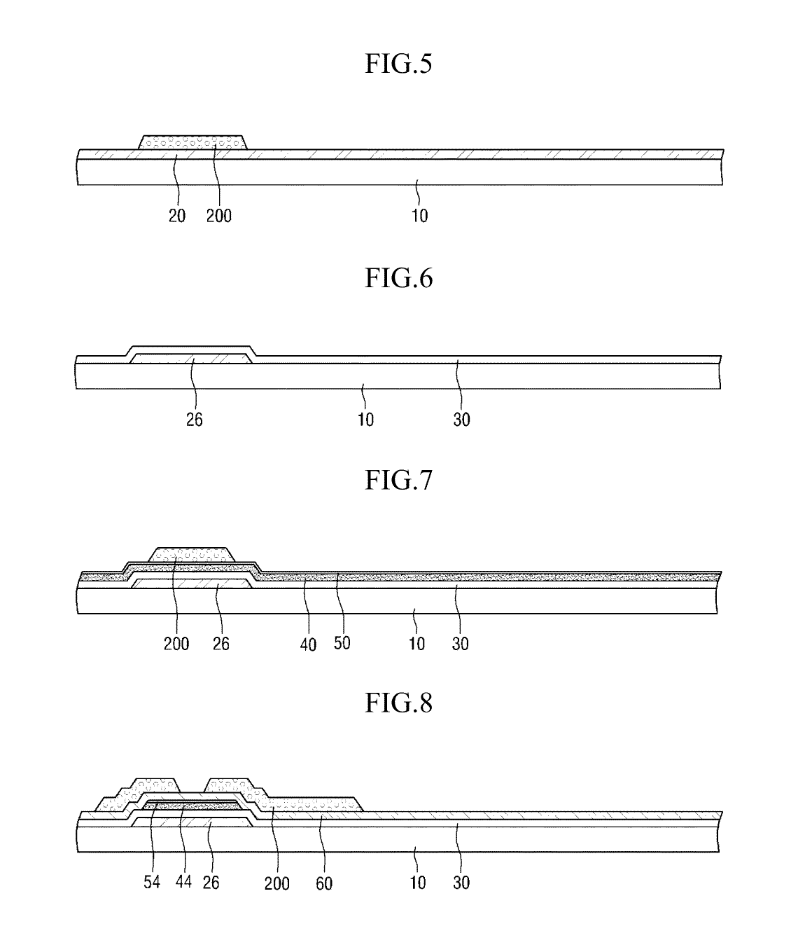

FIGS. 5 through 13 are cross-sectional views illustrating steps of an exemplary method of manufacturing a circuit pattern on a thin-film transistor display panel according to the present invention. The method of manufacturing a circuit pattern according to the exemplary embodiment will now be described in detail with reference to FIGS. 5 through 13.

Referring to FIG. 5, a gate wiring conductive layer 20 is formed on an insulating substrate 10, and an etch pattern 200 is formed on the gate wiring conductive layer 20 using an exemplary photoresist composition according to the invention.

The insulating substrate 10 may be a glass substrate made of soda lime glass or borosilicate glass or a plastic substrate made of polyethersulfone or polycarbonate. In addition, the insulating substrate 10 may be, e.g., a flexible substrate made of polyimide.

The insulating substrate 10 may have a size corresponding to a unit thin-film transistor display panel used in one liquid crystal display (LCD). However, the insulating substrate 10 may also be a large-sized substrate from which a plurality of thin-film transistor display panels is manufactured.

The gate wiring conductive layer 20 may be formed on the insulating substrate 10. The gate wiring conductive layer 20 may be formed by sputtering.

The gate wiring conductive layer 20 may be made of an aluminum (Al)-based metal such as aluminum or an aluminum alloy, a silver (Ag)-based metal such as silver or a silver alloy, copper (Cu)-based metal such as copper or a copper alloy, a molybdenum (Mo)-based metal such as molybdenum or a molybdenum alloy, chrome (Cr), titanium (Ti), or tantalum (Ta).

The gate wiring conductive layer 20 may be patterned using the etch pattern 200 as an etch mask, and the patterned gate wiring conductive layer 20 may form gate wiring which includes a gate line (not illustrated) and a gate electrode 26 (see FIG. 6). The gate wiring conductive layer 20 may be patterned using a wet etching process or a dry etching process.

In the wet etching process, a mixture of deionized water and hydrofluoric acid (HF), sulfuric acid, hydrochloric acid or any combination of the same may be used. In the dry etching process, a fluorine-based etching gas such as trifluoromethane (CHF₃) or tetrafluoromethane (CF₄) may be used. Specifically, a fluorine-based etching gas containing Ar or He may be used.

The etch pattern 200 may be formed by coating an exemplary embodiment of a photoresist composition of the invention on the gate wiring conductive layer 20 and then drying, exposing, and developing the photoresist composition.

Referring to FIG. 6, a gate insulating layer 30 is formed on the insulating substrate 10 and the gate electrode 26.

The gate insulating layer 30 may serve as a protective layer that protects the gate electrode 26. The gate insulating layer 30 may be formed by chemical vapor deposition or sputtering. The gate insulating layer 30 may be made of silicon nitride (SiNx) or silicon oxide.

Referring to FIG. 7, an active layer 40, an ohmic contact layer 50, and an etch pattern 200 are sequentially formed on the gate insulating layer 30.

The active layer 40 and the ohmic contact layer 50 may be formed by chemical vapor deposition or sputtering. The active layer 40 is a layer made of an active material having electrical properties when supplied with a driving current. The active material may include, for example, a semiconductor, a metal oxide, etc. The active layer 40 may also be made of hydrogenated amorphous silicon or polycrystalline silicon.

The ohmic contact layer 50 may be made of silicide or n+ hydrogenated amorphous silicon heavily doped with n-type impurities.

The etch pattern 200 may be formed by coating the exemplary photoresist composition according to the invention on the gate wiring conductive layer 20 and then drying, exposing, and developing the photoresist composition. The etch pattern 200 may be formed in an area overlapping the gate electrode 26.

Referring to FIG. 8, an active layer pattern 44 and an ohmic contact layer pattern 54 are formed by patterning the active layer 40 and the ohmic contact layer 50 using the etch pattern 200 of FIG. 7 as an etch mask, and a data wiring conductive layer 60 and etch patterns 200 are sequentially formed.

The active layer pattern 44 and the ohmic contact layer pattern 54 may be formed in the area overlapping the gate electrode 26.

The data wiring conductive layer 60 may be formed by chemical vapor deposition or sputtering. The data wiring conductive layer 60 may be a single layer or multilayer made of at least one of Ni, Co, Ti, Ag, Cu, Mo, Al, Be, Nb, Au, Fe, Se, and Ta. Examples of the multilayer may include a double layer such as TalAl, Ni/Al, Co/Al or Mo(Mo alloy)/Cu, and a triple layer such as Ti/Al/Ti, Ta/Al/Ta, Ti/Al/TiN, Ta/Al/TaN, Ni/Al/Ni or Co/Al/Co.

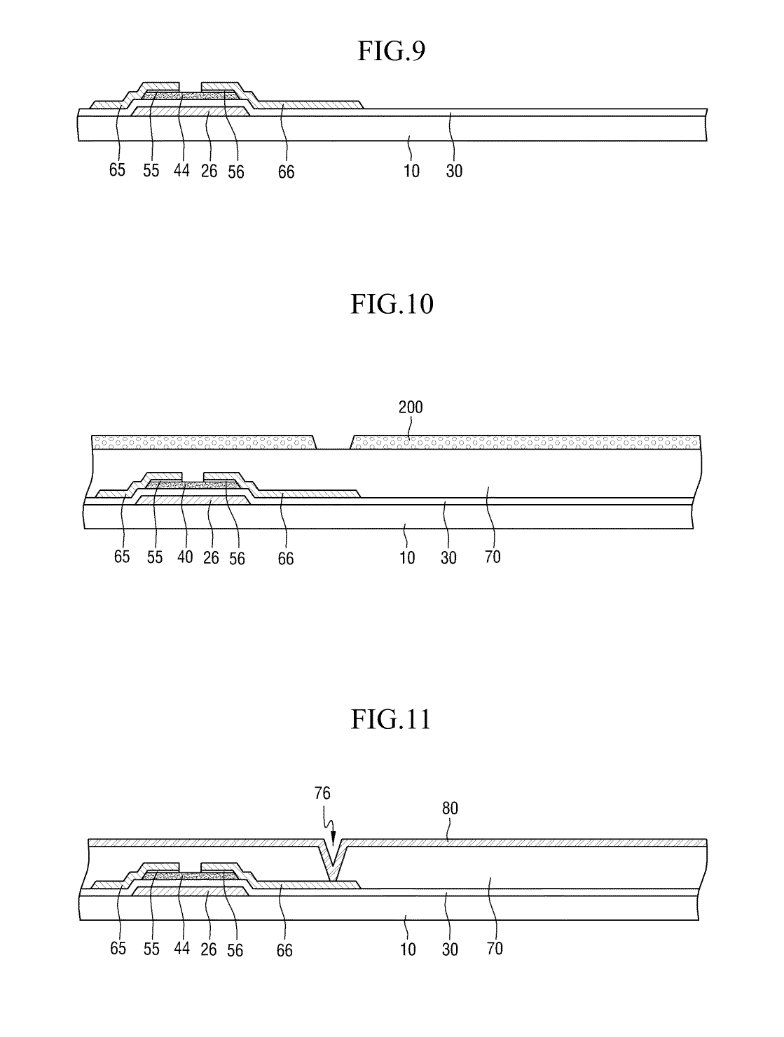

The data wiring conductive layer 60 may be patterned using the etch pattern 200 as an etch mask to form data wiring which includes a data line (not illustrated), a source electrode 65 (see FIG. 9), and a drain electrode 66 (see FIG. 9).

The etch patterns 200 may be formed on the data wiring conductive layer 60 to be separated from each other so as to expose a portion of the data wiring conductive layer 60 formed on the gate electrode 26. The etch patterns 200 may be substantially mirror-symmetrical to each other with respect to the exposed portion of the data wiring conductive layer 60.

Referring to FIG. 9, the source electrode 65 and the drain electrode 66 are formed by patterning the data wiring conductive layer 60 using the etch patterns 200 of FIG. 8 as an etch mask.

The source electrode 65 and the drain electrode 66 are formed in areas protected by the etch patterns 200. In addition, the source electrode 65 and the drain electrode 66 may be mirror-symmetrical to each other on the gate electrode 26 and separated from each other.

In the process of forming the source electrode 65 and the drain electrode 66, the ohmic contact layer pattern 54 may also be etched and thus divided into a plurality of portions. That is, the ohmic contact layer pattern 54 may be patterned into ohmic contact layer patterns 55 and 56 separated from each other, and a portion of the active layer pattern 44 may be exposed in an area between the ohmic contact layer patterns 55 and 56.

The ohmic contact layer pattern 55 is interposed between the source electrode 65 and the active layer pattern 44, and the ohmic contact layer pattern 56 is interposed between the drain electrode 66 and the active layer pattern 44.

Referring to FIG. 10, a planarization layer 70 and etch patterns 200 are formed on the insulating substrate 10 having the source electrode 65 and the drain electrode 66.

The planarization layer 70 may be formed by over-coating a transparent insulating material such as silicon nitride (SiOx) onto the source electrode 65 and the drain electrode 66. A contact hole 76 (see FIG. 11) may be formed in the planarization layer 70 by using the etch patterns 200 formed on the planarization layer 70 as an etch mask. The contact hole 76 may expose a portion of the drain electrode 66. The exposed portion of the drain electrode 66 may directly contact the pixel electrode conductive layer 80 through the contact hole 76.

Referring to FIG. 11, the pixel electrode conductive layer 80 is formed on the planarization layer 70.

The pixel electrode conductive layer 80 may be made of a transparent conductor or a reflective conductor. Examples of a transparent conductor may include indium tin oxide (“ITO”) or indium zinc oxide (“IZO”). The pixel electrode conductive layer 80 may be deposited by sputtering.

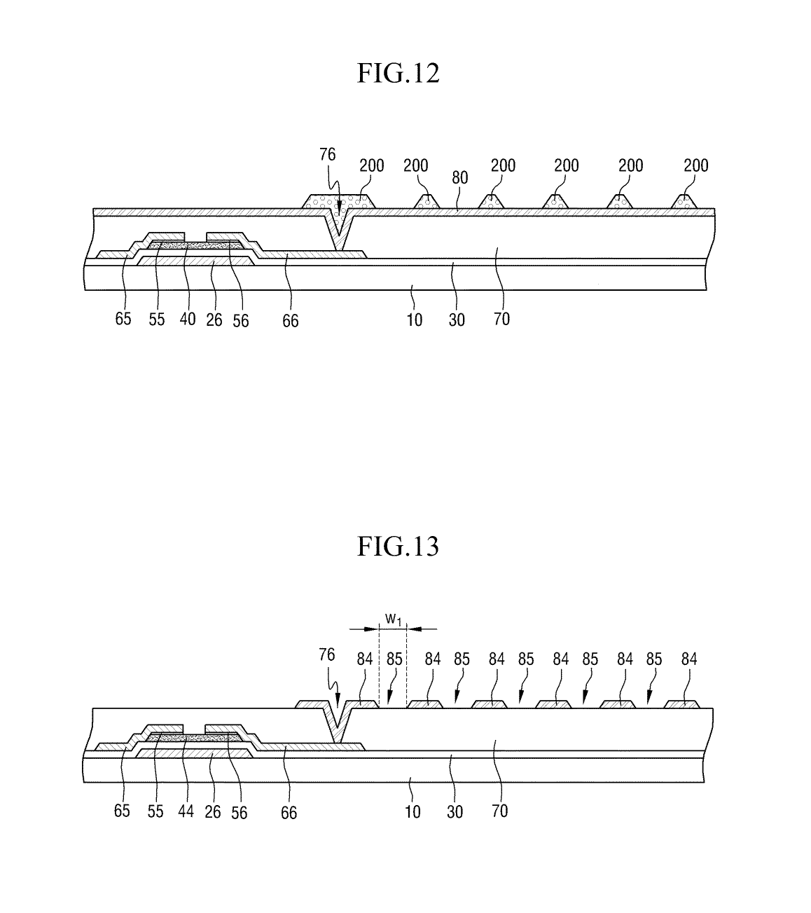

Referring to FIG. 12, etch patterns 200 are formed on the pixel electrode conductive layer 80. Referring to FIG. 13, pixel electrode patterns 84 are formed using the etch patterns 200 as an etch mask.

The pixel electrode patterns 84 may be formed in areas protected by the etch patterns 200 and may be separated by a predetermined width W₁. In other words, a slit 85 having a predetermined width W₁ may be formed between every two of the pixel electrode patterns 84.

While the invention has been particularly shown and described with reference to exemplary embodiments thereof, it will be understood by those of ordinary skill in the art that various changes in form and detail may be made therein without departing from the spirit and scope of the invention as defined by the following claims. The exemplary embodiments should be considered in a descriptive sense only and not for purposes of limitation.

1. A photoresist composition comprising:
an alkali soluble resin;
a photosensitive compound;
a first solvent having a boiling point of less than 200° C.; and
a second solvent having a boiling point of equal to or greater than 200° C., wherein the second solvent is at least one of diethylene glycol monoisopropyl ether, ethylene glycol monohexyl ether, dipropylene glycol dimethyl ether, triethylene glycol dimethyl ether and dimethyl glutarate and a combination thereof.

2. The photoresist composition of claim 1, wherein the alkali soluble resin is at least one of novolac resin, acrylic resin, siloxane resin, or polyimide resin.

3. The photoresist composition of claim 1, wherein the photosensitive compound is a diazide-based photosensitive compound.

4. The photoresist composition of claim 1, wherein the first solvent is at least one of ethyl cellosolve acetate, methyl cellosolve acetate, propylene glycol monoethyl ether acetate, propylene glycol monomethyl ether acetate, ethyl acetate, butyl acetate, propyl acetate, ethyl lactate, propylene glycol monomethyl ether, propylene glycol monoethyl ether; 2-methoxyethyl acetate, methyl 3-methoxypropionate, ethyl 3-ethoxypropionate and a combination thereof.

5. (canceled)

6. The photoresist composition of claim 1, wherein an amount of the alkali soluble resin is about 10% to about 25% by weight, an amount of the photosensitive compound is about 1% to about 10% by weight, an amount of the first solvent is about 65% to about 85% by weight, and an amount of the second solvent is about 1% to about 8% by weight, based on the total weight of the photoresist composition.

7. The photoresist composition of claim 6, wherein the amount of the second solvent is about 5 to about 7% by weight.

8. The photoresist composition of claim 1, wherein the alkali soluble resin is a novolac resin having a meta-cresol to para-cresol ratio of 30:70 to 70:30 by weight.

9. The photoresist composition of claim 1, wherein the photosensitive compound is a diazide-based photosensitive compound selected from at least one of 2,3,4-trihydroxybenzophenone-1,2-naphthoquinonediazide-5-sulfonate, 2,3,4,4-tetrahydroxybenzophenone-1,2-naphthoquinonediazide-5-sulfonate, naphthoquinone-1,2-diazide-5-sulfonyl chloride, naphthoquinone-1,2-diazide-4-sulfonyl chloride and a combination thereof.

10. The photoresist composition of claim 9, wherein the diazide-based photosensitive compound is a combination of 2,3,4-trihydroxybenzophenone-1,2-naphthoquinonediazide-5-sulfonate and 2,3,4,4-tetrahydroxybenzophenone-1,2-naphthoquinonediazide-5-sulfonate, wherein a ratio of 2,3,4-trihydroxybenzophenone-1,2-naphthoquinonediazide-5-sulfonate to 2,3,4,4-tetrahydroxybenzophenone-1,2-naphthoquinonediazide-5-sulfonate is 20:80 to 80:20 by weight.

11. The photoresist composition of claim 1, wherein the first solvent has a vapor pressure of greater than 0.1 torr, and the second solvent has a vapor pressure equal to or greater than 0.1 torr.

12. A method of manufacturing a circuit pattern, the method comprising:
forming a conductive layer on a substrate;
forming an etch pattern on the conductive layer using a photoresist composition, wherein the photoresist composition comprises an alkali soluble resin, a photosensitive compound, and a mixture of a first solvent having a boiling point of less than 200° C. and a second solvent having a boiling point of equal to or greater than 200° C., wherein the second solvent is at least one of diethylene glycol monoisopropyl ether, ethylene glycol monohexyl ether, dipropylene glycol dimethyl ether, triethylene glycol dimethyl ether and dimethyl glutarate and a combination thereof; and
etching the conductive layer using the etch pattern as an etch mask.
